(19) United States
(12) Patent Application Publication
(10) Pub. No.: US 2026/0043128 A1
(43) Pub. Date: Feb. 12, 2026

(54) PROCESSING APPARATUS FOR PROCESSING A FLEXIBLE SUBSTRATE AND METHODS THEREFOR

(71) Applicant: Applied Materials, Inc., Santa Clara, CA (US)

(72) Inventors: Sebastian FRANKE, Hanau (DE); Daniel STOCK, Wetzlar (DE); Manuel FISCHER, Gemünden am Main (DE); Stefan BANGERT, Steinau (DE)

(21) Appl. No.: 18/995,474

(22) PCT Filed: Jul. 26, 2022
(86) PCT No.: PCT/EP2022/070945

§ 371 Date: Jan. 16, 2025

(51) Int. Cl. C23C 16/06; C23C 16/56

(52) U.S. Cl. CPC C23C 16/06; C23C 16/56

(57) ABSTRACT

A processing apparatus for processing a flexible substrate is described. The processing apparatus includes a vacuum processing chamber including at least one deposition source for depositing a layer of material on the flexible substrate. Further, the processing apparatus includes a postprocessing chamber comprising a post-processing roller and a gas supply. The post processing roller has a substrate facing surface comprising a plurality of gas outlets. The gas supply is connected to the post processing roller to provide a gas through the plurality of gas outlets into an interspace between the flexible substrate and the substrate facing surface

### TECHNICAL FIELD

Embodiments of the present disclosure relate to apparatuses and methods for flexible substrate processing, particularly coating of flexible substrates with thin layers, using a roll-to-roll process. In particular, embodiments of the disclosure relate to apparatuses and methods for substrate coating by evaporating a reactive material, such as an alkali metal or an alkaline earth metal, for example lithium.

### BACKGROUND

Various techniques are known for depositing a layer on a substrate, for example, chemical vapor deposition (CVD) and physical vapor deposition (PVD). For coating a substrate at high deposition rates, thermal evaporation may be used as a PVD process. For thermal evaporation, a source material is heated and evaporated to produce a vapor that may be directed onto the substrate for coating the substrate. The temperature for achieving high deposition rates depends on the source material physical properties, e.g. vapor pressure as a function of temperature, and substrate physical limits, e.g. melting point.

For example, the source material to be deposited on the substrate is heated in an evaporation crucible to produce vapor at an elevated vapor pressure. The vapor can stream from the evaporation crucible to a heated vapor distributor with a plurality of nozzles. The vapor may be directed by the plurality of nozzles onto a surface of the substrate that is provided in a vacuum chamber to deposit a coating on the substrate.

Modern thin film lithium batteries may include a lithium coating. The lithium coating is formed, for example, through the deposition of lithium in a vapor state on the substrate. Since lithium is highly reactive, a plurality of measures needs to be addressed to operate and maintain such vapor deposition systems without the risk of safety hazards.

For alkali and alkaline earth metals, some deposition methods are not so amenable to high volume and low-cost manufacturing, because the methods have serious challenges in managing the high reactivity of such materials while scaling to high volume production. This presents challenges in producing uniformly deposited pure lithium. Lithium is of particular interest since lithium is suitable for the production of high energy density batteries and accumulators, i.e. primary batteries and secondary batteries. However, lithium is difficult to handle, e.g. it is challenging to transport, melt and evaporate lithium in a vacuum system, to control a flow rate thereof, and to clean and service the involved components, due to the high reactivity of lithium. Therefore, lithium coatings are often passivated.

In view of the above, it would be beneficial to provide an improved processing apparatus and method for processing a flexible substrate which are suitable for deposition of reactive materials, such as lithium, and with which at least some of the problems of the state of the art can be overcome.

### SUMMARY

In light of the above, a processing apparatus and a method of processing a flexible substrate according to the independent claims are provided. Further aspects, advantages, and features are apparent from the dependent claims, the description, and the accompanying drawings.

According to an aspect of the present disclosure, a processing apparatus for processing a flexible substrate is provided. The processing apparatus includes a vacuum processing chamber including at least one deposition source for depositing a layer of material on the flexible substrate. Further, the processing apparatus includes a post-processing chamber including a post-processing roller and a gas supply. The post processing roller has a substrate facing surface comprising a plurality of gas outlets. The gas supply is connected to the post processing roller to provide a gas through the plurality of gas outlets into an interspace between the flexible substrate and the substrate facing surface.

According to another aspect of the present disclosure a processing apparatus for processing a flexible substrate is provided. The processing apparatus includes a vacuum processing chamber. The vacuum processing chamber includes at least one deposition source for depositing a layer of material on the flexible substrate. Additionally, the vacuum processing chamber includes a post-processing roller. The post processing roller has a substrate facing surface including a plurality of gas outlets. The post processing roller is connected to a gas supply to provide a gas through the plurality of gas outlets into an interspace between the flexible substrate and the substrate facing surface.

According to a further aspect of the present disclosure, a method of processing a flexible substrate is provided. The method includes depositing a material on the flexible substrate. Additionally, the method includes guiding the flexible substrate having a layer of the deposited material over a post-processing roller. Further, the method includes providing a gas through a plurality of gas outlets provided in a substrate facing surface of the post processing roller into an interspace between the flexible substrate and the substrate facing surface.

According to another aspect of the present disclosure, a method of manufacturing a coated flexible substrate is provided. The method includes using at least one of a processing apparatus according to any embodiments described herein and a vacuum processing apparatus according to any embodiments described herein, and a method of processing a flexible substrate according to any embodiments described herein.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic view of a processing apparatus according to embodiments described herein;

FIG. 2 shows a detailed schematic cross-sectional portion of a post-processing roller according to embodiments described herein;

FIG. 3 shows a schematic view of a processing apparatus according to further embodiments described herein;

FIG. 4 shows a block diagram for illustrating a method of processing a flexible substrate according to embodiments described herein, and

FIG. 5 shows a schematic view of a processing apparatus according to further embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

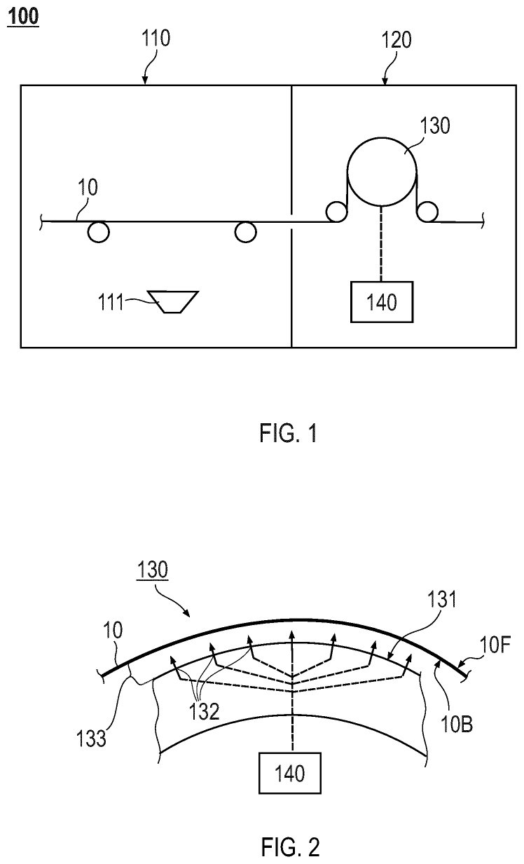

With exemplary reference to FIGS. 1 to 3, a processing apparatus 100 for processing a flexible substrate 10 according to embodiments of the present disclosure is described.

According to embodiments, which can be combined with any other embodiments described herein, the processing apparatus 100 includes a vacuum processing chamber 110, as exemplarily shown in FIG: 1. The vacuum processing chamber 110 includes at least one deposition source 111 for depositing a material on the flexible substrate 10. In particular, the vacuum processing chamber 110 typically includes a processing drum 105 for guiding the flexible substrate past the at least one deposition source 111. The processing drum 105 may also be referred to as coating drum. Further, the processing apparatus 100 may include a post-processing chamber 120 including a post-processing roller 130 and a gas supply 140. Alternatively, the post processing roller 130 may be provided within the vacuum processing chamber 110. The post processing roller 130 has a substrate facing surface 131 comprising a plurality of gas outlets 132, as schematically shown in FIG. 2. The gas supply 140 is connected to the post processing roller 130 to provide a gas through the plurality of gas outlets 132 into an interspace 133 between the flexible substrate and the substrate facing surface 131.

Accordingly, beneficially an improved processing apparatus for processing a flexible substrate is provided. In particular, providing the processing apparatus with a separate post processing roller with a gas supply beneficially provides for the possibility to provide a post-processing gas to the processed substrate surface more effectively. As a result, the transportation speed of the flexible substrate through the processing system can be increased without detrimentally affecting the post-processing quality. Further, employing a separate post processing roller configured for applying a post-processing gas to the processed substrate surface, provides for the possibility to apply the post-processing gas at elevated gas pressures which further improves the quality of the post-processing. In other words, employing a post processing roller being configured as a gas cushion drum for providing a post-processing gas, particularly a passivation gas, e.g. for the passivation of a lithium layer or coating, increases the effectiveness of the gas exposure to the surface to be post-processed, particularly passivated. Further, beneficially higher passivation gas pressures and more passivation gas molecules can be provided to the substrate surface to be passivated, which allows for increased substrate transportation speed, and a lower pressure in the post processing chamber, which may be a re-winding chamber including a take-up roll for taking-up the processed substrate. Further, it is to be noted that compared to the state of the art, higher passivation gas pressures and more passivation gas molecules can be provided to the substrate surface to be passivated, while at the same time the deposition process, for example in an adjacent vacuum processing chamber or within the same vacuum chamber, is not affected.

Before various further embodiments of the present disclosure are described in more detail, some aspects with respect to some terms used herein are explained.

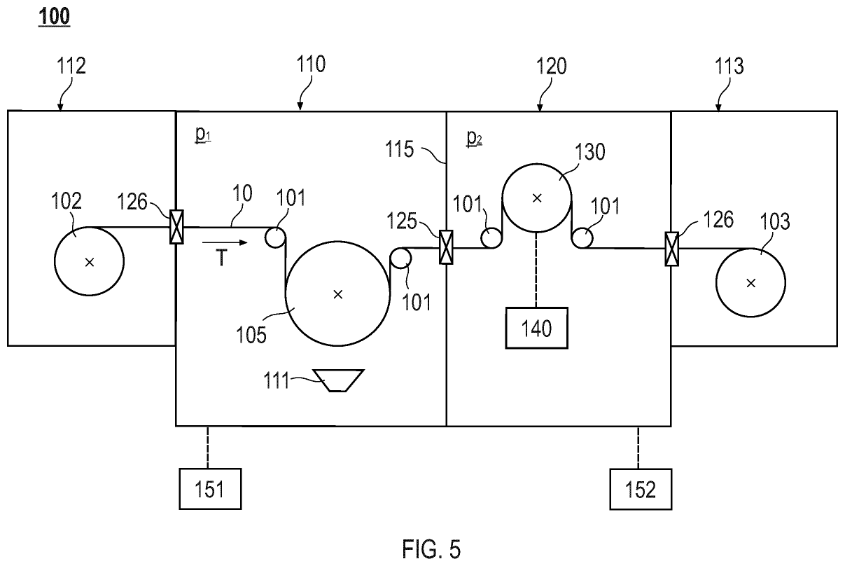

In the present disclosure, a “processing apparatus for processing a flexible substrate” can be understood as an apparatus configured for processing, particularly coating, a flexible substrate. In particular, the processing apparatus can be a roll-to-roll (R2R) processing system. A roll-to-roll processing system can be understood as a processing system having a plurality of rollers for guiding the substrate along a substrate transportation path. For example, as exemplarily described in more detail with reference to FIG. 5 in the following, the roll-to-roll processing system may include a supply roller 102, a plurality of guiding rollers 101, a processing drum 105, a post-processing drum 130, and a take-up roller 103.

Typically, the processing apparatus includes at least one vacuum processing chamber configured for providing a coating on the flexible substrate. A coating on the flexible substrate can be understood as a layer of material deposited on the flexible substrate, e.g. by using a deposition source as described herein. A vacuum processing chamber can be understood as a chamber adapted for carrying out a processing, e.g. depositing a layer of material, on the substrate under vacuum conditions. Accordingly, the vacuum processing chamber may also be referred to as vacuum deposition chamber. In the present disclosure, the term “vacuum” can be understood in the sense of a technical vacuum having a vacuum pressure of less than, for example, 10 mbar. Typically, the pressure in a vacuum chamber as described herein may be between 10⁻⁵ mbar and about 10⁻⁸ mbar, more typically between 10⁻⁵ mbar and 10⁻⁷ mbar, and even more typically between about 10⁻⁶ mbar and about 10⁻⁷ mbar.

In the present disclosure, a “flexible substrate” or “thin film substrate” can be understood as a bendable substrate. For instance, the “flexible/thin film substrate” can be a “foil” or a “web”. In the present disclosure the term “flexible substrate”, the term “substrate” and the term “thin film substrate” may be synonymously used. For example, the flexible substrate as described herein may be made of or include materials like PET, HC-PET, PE, PI, PU, TaC, OPP, BOOP, CPP, one or more metals (e.g. copper), paper, combinations thereof, and already coated substrates like Hard Coated PET (e.g. HC-PET, HC-TaC) and the like. In some embodiments, the flexible substrate is a COP substrate provided with an index matched (IM) layer on both sides thereof. For example, the substrate thickness can be 1 μm or more and 1 mm or less, particularly 500 μm or less, or even 200 μm or less. Further particularly, substrates may have a thickness of 4 μm. The substrate width WS can be 0.1 m≤W≤6 m. The substrate may be a transparent or non-transparent substrate. Particularly, the substrate may be a metal foil, e.g. a copper foil.

In the present disclosure, a “post-processing chamber” can be understood as a chamber configured to carry out a post-processing of a previously processed, particularly coated, substrate. Accordingly, it is to be understood that the post-processing chamber is typically arranged downstream from the main processing chamber, e.g. a vacuum deposition chamber.

In the present disclosure, a “post-processing roller” can be understood as a roller or drum configured for carrying out a post-processing on a processed surface, particularly a coated surface, of the flexible substrate. Typically, the post-processing roller has a substrate facing surface for contacting the flexible substrate. The substrate facing surface may be seen as a part or region of the post-processing roller that faces and/or guides the substrate. For example, the substrate facing surface may be understood as a surface of the roller that is adjacent to the substrate or that may contact the substrate. Particularly, the substrate facing surface may be adjacent to a surface of the substrate that is turned away from a surface of the substrate that is coated during a coating or deposition process. The substrate facing surface typically includes a substrate facing surface portion, i.e. a portion of the post-processing roller over which the substrate is guided or where the substrate is in contact with the substrate facing surface of the post-processing roller. Since the substrate is moved via the roller, the substrate facing surface portion may change continuously, i.e. the substrate facing surface portion may correspond to the respective portion of the substrate that is adjacent to the roller or in contact with the post-processing roller to a given point in time during transport (by rotation of the post-processing roller) of the substrate.

Typically, the substrate facing surface is a curved outer surface, particularly a cylindrical outer surface, of the post-processing roller. Accordingly, typically the post-processing roller is rotatable about a rotation axis of the post-processing roller. It is to be understood that the substrate facing surface portion is a part of the curved substrate facing surface, e.g. a cylindrically symmetric surface, of the post-processing roller. The curved substrate facing the surface of the post-processing roller may be adapted to be (at least partly) in contact with the flexible substrate during the guiding of the flexible substrate. The substrate facing surface portion may be defined as an angular range of the post-processing roller over which the substrate is guided or may be in contact with the flexible substrate during the guiding of the substrate. For instance, the substrate facing surface portion may correspond to the enlacement angle of the post-processing roller. For instance, the enlacement angle of the post-processing roller may be 90°or more, particularly 180°or more, or even 270°or more. According to some embodiments, which can be combined with other embodiments described herein, the post-processing roller 100 is cylindrical and has a length L of 0.2 m≤L≤8.5 m. Further, the roller may have a diameter D of 0.1 m≤D≤3.0 m. Accordingly, beneficially the roller is configured for guiding and transporting flexible substrates having a large width. Yet further, the post-processing roller may be a segmented gas cushion roller which is configured for providing the post-processing gas specifically to the contact region of the substrate with the post-processing roller, particularly during substrate guiding.

According to some embodiments, which can be combined with other embodiments described herein, a first subgroup of gas outlets, i.g. open gas outlets, can be provided in a substrate guiding region of the post-processing roller. A second subgroup of gas outlets, e.g. closed gas outlets, can be provided outside the substrate guiding region. Since gas is only emitted in the substrate guiding region where it is needed, no or little gas is directly emitted into a region not overlapped by the substrate. Accordingly, waste of gas may be reduced and/or a better gas separation between vacuum processing chamber and post-processing chamber can be obtained.

According to some embodiments, which can be combined with other embodiments described herein, additionally or alternatively to the subgroups of gas outlets, the outer surface of the post-processing roller may be coated with a microporous surface. The microporous surface may allow for a small amount of gas to flow from inside the post-processing roller to the surface of the post-processing roller. The gas may form a gas cushion between the post-processing roller and the flexible substrate guided over the post-processing drum. In particular, the gas cushion is provided in the interspace between the flexible substrate and the substrate facing surface.

In the present disclosure, a “gas supply” can be understood as a system configured for providing a supply of gas. For instance, the gas supply may be understood as a gas distribution system configured for providing a gas flow through the one or more gas outlets of the post-processing roller, particularly into the interspace between the flexible substrate and the substrate facing surface. As exemplarily shown in FIG. 1, the gas supply can be connected to the post-processing roller. The person skilled in the art may understand that the gas supply may also be provided (at least partly) within the roller. More specifically, the gas supply may be connected to the roller and may supply a gas flow through the one or more gas outlets arranged in the surface of the roller. Inside the roller, gas supply channels may be provided. The gas supply channels may be connected to the one or more gas outlets. Particularly, the gas flow may be provided at the substrate facing surface portion, i.e. the gas flow may be supplied through the one or more gas outlets where the substrate may contact or be guided along the substrate facing surface. A distance between the substrate and the substrate facing surface of the roller, i.e. a dimension of the interspace between the substrate and the substrate facing surface, may vary according to the pressure with which the gas flow may be provided towards the substrate and the tension applied to the substrate. Advantageously, the gas flow may be provided for preventing the substrate from directly contacting the post-processing roller. Accordingly, the post-processing roller as described herein may be referred to as gas cushion post-processing roller.

According to embodiments, which can be combined with any other embodiments described herein, the gas supply 140 provides a passivation gas for passivating the layer of material deposited on the flexible substrate. In other words, typically the gas supply 140 is configured to provide a passivation gas. For instance, the gas supply 140 may include a gas tank with the passivation gas. In particular, the passivation gas may be carbon dioxide, nitrogen, oxygen, ozone, water vapor, or any mixture thereof.

According to embodiments, which can be combined with any other embodiments described herein, the at least one deposition source 111 is configured for depositing an alkali metal, particularly lithium, or an alkaline earth metal on the flexible substrate 10. For example, the at least one deposition source 111 may be an evaporation source having a crucible including the source material to be deposited. The source material may be heated inside the crucible above the evaporation temperature of the source material. The evaporated material may then be guided in a vapor distributor toward a plurality of nozzles for directing the evaporated material toward the flexible substrate.

According to embodiments, which can be combined with any other embodiments described herein, the at least one deposition source 111 may include a plurality of deposition sources which can be arranged in a circumferential direction around the processing drum 105. As the processing drum rotates, the flexible substrate 10 is guided past the plurality of deposition sources which face toward the substrate front surface 10F, so that the front surface 10F of the substrate 10 can be coated while being moved past the deposition sources at a predetermined speed. For example, the plurality of deposition sources may include one or more units selected from the group consisting of: a sputter deposition unit, e.g. an AC (alternating current) sputter source or a DC (direct current) sputter source, a RF (radio frequency) sputter source, a MF (middle frequency) sputter source, a pulsed sputter source, a pulsed DC sputter source, a magnetron sputter source, a reactive sputter source, a CVD deposition unit, a PECVD deposition unit, a PVD deposition unit or another suitable deposition unit. It is to be understood that typically a deposition unit as described herein is adapted for depositing a thin film on a flexible substrate, e.g., to form a flexible display device, a touch-screen device component, or other electronic or optical devices. A deposition source as described herein can be configured for depositing at least one material selected from the group of conductive materials, semi-conductive materials, dielectric materials, isolating materials, an alkali metal, particularly lithium, or an alkaline earth metal.

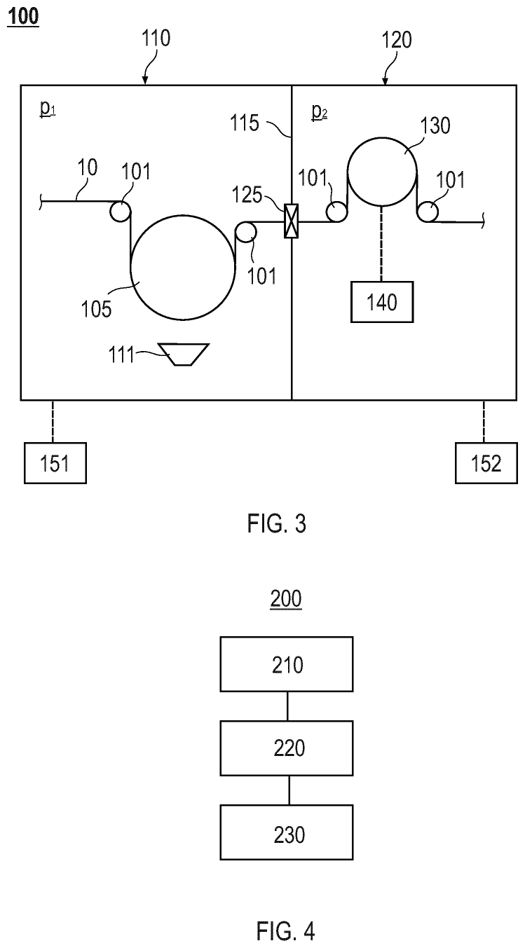

According to embodiments, which can be combined with any other embodiments described herein, the vacuum processing chamber is configured for processing at a processing pressure p₁ of p₁≤1×10⁻⁴ mbar. In particular, the vacuum processing chamber 110 can be connected to a first vacuum pump 151 configured for providing the processing pressure p₁, as exemplarily shown in FIG. 3

According to embodiments, which can be combined with any other embodiments described herein, the post-processing chamber 120 is configured for post-processing at a post processing pressure p₂ of p₂≤1×10⁻¹ mbar. In particular, the post-processing chamber can be connected to a second vacuum pump 152 configured for providing the post processing pressure p₂, as exemplarily shown in FIG. 3.

According to embodiments, which can be combined with any other embodiments described herein, the gas supply 140 is configured for providing a gas pressure p_{g} of 1 mbar≤p_{g}≤100 mbar, particularly 1 mbar≤p_{g}≤50 mbar, into the interspace 133 between the flexible substrate 10 and the substrate facing surface 131.

According to embodiments, which can be combined with any other embodiments described herein, the gas supply 140 is configured for providing a gas flow rate between 1 and 200 sccm, particularly a gas flow rate <50 sccm, into the interspace 133 between the flexible substrate and the substrate facing surface 131.

With exemplary reference to FIG. 3, according to embodiments which can be combined with any other embodiments described herein, the vacuum processing chamber 110 is separated from the post-processing chamber 120 by a sealing 125. Typically, the sealing 125 is provided in a wall 115 between the vacuum processing chamber 110 and the post-processing chamber 120. Further, the sealing is configured for allowing transfer of the flexible substrate from the vacuum processing chamber 110 into the post-processing chamber 120. The sealing 125 can be configured to separate, at least substantially, the pressure conditions of the vacuum processing chamber 110 (e.g. at a processing pressure pi) and the post-processing chamber 120 (e.g. at a post processing pressure p₂).

For example, the sealing 125 may include an inflatable seal configured to press the substrate against a flat sealing surface. Accordingly, the opening in the wall 115 between the vacuum processing chamber 110 and the post-processing chamber 120 can be sealed, even when the flexible substrate may be present in the opening. In other words, removal of the flexible substrate may not be necessary for closing or opening the sealing 125. Alternatively, the sealing 125 can be provided by a gap sluice or load-lock valve for separating the vacuum processing chamber 110 from the post-processing chamber 120. It is to be understood that the gap sluice or the load-lock valve are configured such that the flexible substrate 10 can move therethrough while maintaining the different pressure conditions in the vacuum processing chamber 110 and the post-processing chamber 120.

With exemplary reference to FIG. 5, according to embodiments which can be combined with any other embodiments described herein, the processing apparatus 100 may include a supply chamber 112, a vacuum processing chamber 110, a post-processing chamber 120, and an optional take-up chamber 113. Typically, the supply chamber 112 includes a supply roller 102. In other words, the supply chamber 112 is configured for housing the supply roller 102 with the flexible substrate wound thereon. During operation, the flexible substrate 10 can be unwound from the supply roller 102 and transported along the substrate transportation path in the transportation direction T from the supply chamber 112 through the vacuum processing chamber 110 and the post-processing chamber 120 to the take-up chamber 113. The take-up chamber 113 typically includes a take-up roller 103 adapted for receiving the processed substrate. According to an example (not explicitly shown), the take-up roller 103 may be provided in the post-processing chamber 120. Accordingly, it is to be understood that, according to embodiments which can be combined with any other embodiments described herein, the processing apparatus 100 can further include at least one of: a supply chamber 112 housing a supply roller 102 for providing an unprocessed flexible substrate, and a take-up chamber 113 housing a take-up roller 103 for taking up the processed flexible substrate.

With exemplarily reference to FIG. 5, according to embodiments, which can be combined with any other embodiments described herein, one or more further sealings 126 may be provided between adjacent chambers of the processing system. For example, a further sealing 126 may be provided in a wall between the supply chamber 112 and the vacuum processing chamber 110. Additionally or alternatively, a further sealing 126 may be provided in a wall between the post-processing chamber 120 and the take-up chamber 113. It is to be understood that the one or more further sealings 126 can be configured as the sealing 125 provided between the vacuum processing chamber 110 and the post-processing chamber 120 as described herein.

According to embodiments, which can be combined with any other embodiments described herein, the processing drum 105 can be a gas cushion roller which may be configured similarly to the post processing roller 130. The processing drum 105 being a gas cushion drum may be connected to a cooling gas supply (not explicitly shown) for providing a cooling gas to a back side 10B of the flexible substrate 10 during material deposition. Accordingly, it is to be understood that the processing apparatus 100 may include two or more gas cushion rollers, e.g. a first gas cushion roller (e.g. the processing drum 105) provided in the processing chamber and being configured for providing a cooling gas and a second gas cushion roller (e.g. the post processing roller 130) provided in the post-processing chamber and being configured for providing a post-processing gas as described herein.

With exemplary reference to the block diagram shown in FIG. 4, a method 200 of processing a flexible substrate 10 according to the present disclosure is described. According to embodiments, which can be combined with any other embodiments described herein, the method 200 includes depositing (represented by block 210 in FIG. 4) a material on the flexible substrate 10. Additionally, the method 200 includes guiding (represented by block 220 in FIG. 4) the flexible substrate having a layer of the deposited material over a post-processing roller 130. Further, the method includes providing (represented by block 230 in FIG. 4) a gas through a plurality of gas outlets 132 provided in a substrate facing surface 131 of the post processing roller 130 into an interspace between the flexible substrate 10 and the substrate facing surface 131. It is to be understood that the method 200 of processing a flexible substrate 10 can be carried out by using a processing apparatus 100 according to any embodiments described herein.

According to embodiments, which can be combined with any other embodiments described herein, the gas provided through the plurality of gas outlets 132 is a passivation gas for passivating the layer of deposited material. For instance, the passivation gas can be carbon dioxide or any other suitable gas for passivating the layer of deposited material, particularly for passivating a layer or coating of an alkali metal, particularly lithium, or an alkaline earth metal.

For example, freshly coated lithium (Li) is highly reactive with water and air. For battery applications, the Li coated substrate roll can be passivated, e.g. with CO₂ gas, to form a defined and more stable Li₂CO₃ surface on top of the Li layer. Accordingly, the risk of damaging the coating can be reduced and substrate handling and transport is facilitated. For instance, the thickness Tₚ of the passivation layer, e.g. of Li₂CO₃, can be 2 nm≤Tₚ≤20 nm, e.g. Tₚ=10 nm±2 nm. The thickness Tc of the coating to be passivated, e.g. the thickness of the Li coating, can be 1 μm≤T_{c}≤30 μm, e.g. Tₚ=10 μm±2 μm. Accordingly, the thickness Tₚ of the passivation layer can be three orders of magnitude smaller than the thickness T_{c} of the coating.

According to embodiments, which can be combined with any other embodiments described herein, depositing (represented by block 210 in FIG. 4) a material on the flexible substrate includes depositing an alkali metal, particularly lithium, or an alkaline earth metal on the flexible substrate.

According to embodiments, which can be combined with any other embodiments described herein, depositing (represented by block 210 in FIG. 4) the material on the flexible substrate is carried out in a vacuum processing chamber 110 at a processing pressure p₁ of p₁≤1×10⁻⁴.

According to embodiments, which can be combined with any other embodiments described herein, guiding (represented by block 220 in FIG. 4) the flexible substrate having the layer of the deposited material over the post-processing roller 130 is carried out in a post-processing chamber 120 at a post processing pressure p₂ of p₂≤1×10⁻¹ mbar.

According to embodiments, which can be combined with any other embodiments described herein, providing (represented by block 230 in FIG. 4) the gas through the plurality of gas outlets 132 includes providing a gas pressure p_{g} of 1 mbar≤p_{g}≤100 mbar, particularly 1 mbar≤p_{g}≤10 mbar, into the interspace 133 between the flexible substrate 10 and the substrate facing surface 131.

According to embodiments, which can be combined with any other embodiments described herein, providing (represented by block 230 in FIG. 4) the gas through the plurality of gas outlets 132 includes providing a gas flow rate between 1 and 200 sccm, particularly a gas flow rate <50 sccm, into the interspace between the flexible substrate and the substrate facing surface 131.

In view of the embodiments described herein, it is to be understood that according to an aspect of the present disclosure, a method of manufacturing a coated flexible substrate can be provided. The method includes using at least one of a processing apparatus 100 according to any embodiments described herein and a method 200 of processing a flexible substrate according to any embodiments described herein. In particular, the method of manufacturing a coated flexible substrate may be a method of manufacturing a passivated lithium coated flexible substrate.

According to yet further embodiments, a method of manufacturing an anode of a battery is provided. The method of manufacturing the anode includes carrying out a method 200 of processing a flexible substrate according to any of the embodiments described herein. In particular, the method of manufacturing the anode may include guiding a flexible substrate including an anode layer in a processing apparatus 100 according to any the embodiments described herein and depositing a lithium containing material or lithium on the flexible substrate with a deposition source according to any of the embodiments described herein.

In view of the above, it is to be understood that compared to the state of the art, embodiments as described herein provide for an improved processing apparatus for processing a flexible substrate and an improved method of processing a flexible substrate, particularly for battery applications, e.g. lithium batteries. In particular, embodiments of the present disclosure beneficially provide for a more effective application of a post processing gas, particularly for passivation of a coating provided on a flexible substrate. As a result, the transportation speed of the flexible substrate through the processing system can be increased without detrimentally affecting the post-processing quality. Thus, embodiments of the present disclosure beneficially provide for an improvement of the overall productivity.

While the foregoing is directed to embodiments, other and further embodiments may be devised without departing from the basic scope, and the scope is determined by the claims that follow.

1. A processing apparatus for processing a flexible substrate, comprising:
a vacuum processing chamber comprising at least one deposition source for depositing a layer of material on the flexible substrate, and
a post-processing chamber comprising a post-processing roller and a gas supply wherein the post processing roller has a substrate facing surface comprising a plurality of gas outlets, and
wherein the gas supply is connected to the post processing roller to provide a gas through the plurality of gas outlets into an interspace between the flexible substrate and the substrate facing surface.

2. The processing apparatus according to claim 1, wherein the gas supply provides a passivation gas, for passivating the layer of material deposited on the flexible substrate.

3. The processing apparatus according to claim 1, wherein the at least one deposition source is configured for depositing as least one material selected from the group consisting of alkali metal, lithium, an alkaline earth metal, on the flexible substrate.

4. The processing apparatus according to claim 1, wherein the vacuum processing chamber is configured for processing at a processing pressure p₁ of p₁≤1×10⁻⁴ mbar.

5. The processing apparatus according to claim 1, wherein the post-processing chamber is configured for post-processing at a post processing pressure p₂ of p₂≤1×10⁻¹ mbar.

6. The processing apparatus according to claim 1, wherein the gas supply provides a gas pressure p_{g} of 1 mbar≤p_{g}≤100 mbar, into the interspace between the flexible substrate and the substrate facing surface.

7. The processing apparatus according to claim 1, wherein the gas supply provides a gas flow rate between 1 and 200 sccm into the interspace between the flexible substrate and the substrate facing surface.

8. The processing apparatus according to claim 1, wherein the vacuum processing chamber is separated from the post-processing chamber by a sealing.

9. The processing apparatus according to claim 1, the vacuum processing chamber further comprising a processing drum for guiding the flexible substrate past the at least one deposition source, and the processing apparatus further comprising at least one of a supply chamber housing a supply roller for providing an unprocessed flexible substrate, and a take-up chamber housing a take-up roller for taking up the processed flexible substrate.

10. A processing apparatus for processing a flexible substrate, comprising a vacuum processing chamber, the vacuum processing chamber comprising at least one deposition source for depositing a layer of material on the flexible substrate and a post-processing roller, the post processing roller having a substrate facing surface comprising a plurality of gas outlets, the post processing roller being connected to a gas supply to provide a gas through the plurality of gas outlets into an interspace between the flexible substrate and the substrate facing surface.

11. A method of processing a flexible substrate, comprising:
depositing a material on the flexible substrate, and
guiding the flexible substrate having a layer of the deposited material over a post-processing roller, and
providing gas through a plurality of gas outlets provided in a substrate facing surface of the post processing roller into an interspace between the flexible substrate and the substrate facing surface.

12. The method according to claim 11, wherein the gas is a passivation for passivating the layer of deposited material.

13. The method according to claim 11, wherein depositing the material includes depositing at least one material selected from the group consisting of alkali metal, lithium, and alkaline earth, metal on the flexible substrate.

14. The method according to claim 11, wherein depositing the material on the flexible substrate is carried out in a vacuum processing chamber at a processing pressure p₁ of p₁≤1×10⁻⁴ mbar, and wherein guiding the flexible substrate having the layer of the deposited material over the post-processing roller is carried out in a post-processing chamber at a post processing pressure p₂ of p₂≤1×10⁻¹ mbar.

15. The method according to claim 11, wherein providing the gas through the plurality of gas outlets comprises providing a gas pressure p_{g} of 1 mbar≤p_{g}≤100 mbar, into the interspace between the flexible 5 substrate and the substrate facing surface.

16. The method according to claim 11, wherein providing the gas through the plurality of gas outlets comprises providing a gas flow rate between 1 and 200 sccm into the interspace between the flexible substrate and the substrate facing surface.

17. A method of manufacturing a coated flexible substrate, comprising using at least one of a processing apparatus according claim 1 and a method of processing a flexible substrate according to claim 11.

18. The method according to claim 11, wherein the gas is carbon dioxide.

19. The method according to claim 11, wherein providing the gas through the plurality of gas outlets comprises providing a gas pressure p_{g} of 1 mbar≤p_{g}≤10 mbar into the interspace between.

20. The method according to claim 11, wherein providing the gas through the plurality of gas outlets comprises providing a gas flow rate <50 sccm into the interspace between the flexible substrate and the substrate facing surface.
